(19) United States
(12) Patent Application Publication
(10) Pub. No.: US 2011/0303981 A1
(43) Pub. Date: Dec. 15, 2011

(54) Scheme to Enable Robust Integration of Band Edge Devices and Alternatives Channels

(75) Inventors: Lisa F. Edge, Albany, NY (US); Hemanth Jagannathan, Albany, NY (US); Bala Subramanian Haran, Albany, NY (US)

(73) Assignee: International Business Machines Corporation, Armonk, NY (US)

(21) Appl. No.: 12/797,431

(22) Filed: Jun. 9, 2010

(51) Int. Cl. H01L 27/12; H01L 21/20

(52) U.S. Cl. 257/351; 438/481; 257/E21.119; 257/E27.112

(57) ABSTRACT

A method of forming a semiconductor device includes forming a buried oxide (BOX) layer on a semiconductor substrate, forming a silicon-on-insulator (SOI) layer on the BOX layer, depositing a hard mask including one of silicon, a nitride, and a metal oxide on the SOI layer, removing the hard mask from a first region of the semiconductor device, performing a cleaning process on the semiconductor device, wherein the hard mask is not removed from a second region of the semiconductor device by the cleaning process, epitaxially growing a semiconductor material in the first region of the semiconductor device, and removing the hard mask from the second region of the semiconductor device.

### BACKGROUND

1. Technical Field

The present disclosure relates to a field effect transistor (FET) device and a fabrication method therefore.

2. Discussion of Related Art

Typical CMOS integrated circuits include both n-type (nFET) and p-type (pFET) field effect transistors to be fabricated in close proximity to each other. Continued scaling of CMOS devices has led to small gate pitch (˜0.7× per generation) and SRAM area scaling (˜0.5× per generation) in conjunction with reduction in transistor delay and leakage. Improving performance without causing leakage is a key factor in the fabrication of CMOS integrated circuits. To achieve high performance and low leakage, alternative channel materials are being considered in lieu of silicon.

One material being actively pursued for pFET devices is crystalline silicon-germanium (c-SiGe) epitaxially grown on silicon. Typically, pFET devices are adjacent to nFET devices during fabrication. Prior to epitaxy, a hard mask is deposited over the nFET devices to confine the growth of c-SiGe to the pFET devices. This hard mask is typically formed of silicon dioxide (SiO₂). Several cleaning steps must be performed on the semiconductor device prior to epitaxy. Repetition of these cleaning steps may result in the removal of the SiO₂ hard mask above the nFET devices. As a result, the number of cleaning steps that may be performed is limited, otherwise cleaning may result in the removal of the hard mask above the nFET devices. When this occurs, c-SiGe may be inadvertently grown in regions of the nFET devices during epitaxy.

Therefore, a need exists for a hard mask that can be used with alternative channel materials and can withstand a number of cleaning steps performed during fabrication of the semiconductor device.

### BRIEF SUMMARY

According to an exemplary embodiment of the present disclosure, a method of forming a semiconductor device includes forming a buried oxide (BOX) layer on a semiconductor substrate, forming a silicon-on-insulator (SOI) layer on the BOX layer, depositing a hard mask on the SOI layer, removing the hard mask from a first region of the semiconductor device, performing a cleaning process on the semiconductor device, epitaxially growing a semiconductor material in the first region of the semiconductor device, and removing the hard mask from a second region of the semiconductor device. The hard mask is formed of at least one of silicon, a nitride and a metal oxide. The hard mask is not removed from the second region of the semiconductor device by the cleaning process.

According to an exemplary embodiment of the present disclosure, a semiconductor device comprises a buried oxide layer (BOX) layer formed on a semiconductor substrate, a silicon-on-insulator (SOI) layer formed on the BOX layer, a semiconductor material epitaxially grown in a first region of the semiconductor device, and a hard mask formed on a second region of the semiconductor device. The hard mask includes at least one of silicon, a nitride and a metal oxide.

### BRIEF DESCRIPTION OF THE SEVERAL VIEWS OF THE DRAWINGS

Preferred embodiments of the present disclosure will be described below in more detail, with reference to the accompanying drawings:

FIG. 1 depicts a semiconductor device comprising a pFET and nFET region in close proximity separated by an isolation layer, according to an exemplary embodiment of the present disclosure.

FIGS. 2A-2B depict a hard mask on the top surface of the semiconductor device, according to an exemplary embodiment of the present disclosure.

FIGS. 3A-3B depict the etching away of a portion of a hard mask on the semiconductor device and patterning the semiconductor device with a photoresist layer, according to an exemplary embodiment of the present disclosure.

FIG. 4 depicts the semiconductor device after a cleaning process has been performed, according to an exemplary embodiment of the present disclosure.

FIGS. 5A-5C depict a semiconductor material being epitaxially grown on a top surface of p-channel regions of the semiconductor device, according to an exemplary embodiment of the present disclosure.

FIGS. 6A-6B depict a semiconductor material and a silicon cap being epitaxially grown on a top surface of p-channel regions of the semiconductor device, according to an exemplary embodiment of the present disclosure.

FIG. 7 is a cross-sectional view of a semiconductor device depicting the presence of a hard mask above a top surface of n-channel regions of the semiconductor device after the hard mask has been patterned, according to an exemplary embodiment of the present disclosure.

FIG. 8 is a cross-sectional view depicting the epitaxial growth of c-SiGe according to an exemplary embodiment of the present disclosure.

### DETAILED DESCRIPTION

Exemplary embodiments of the present disclosure now will be described more fully hereinafter with reference to the accompanying drawings.

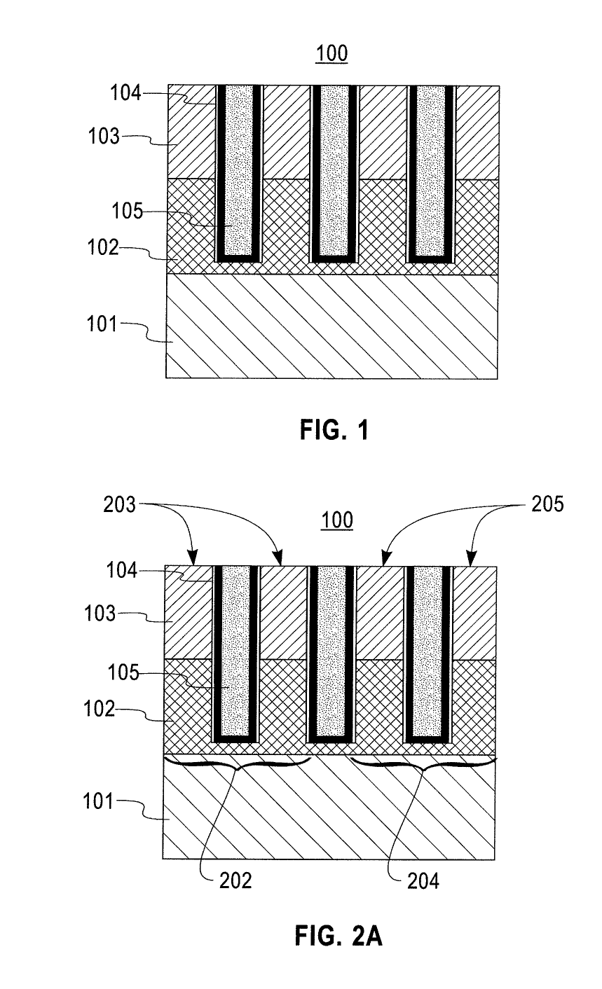

FIG. 1 depicts a semiconductor device 100 comprising a pFET and nFET region in close proximity separated by an isolation layer such as, for example, shallow trench isolation, according to an exemplary embodiment of the present disclosure.

Referring to FIG. 1, the device 100 may include a plurality of layers. For example, the device 100 may include a semiconductor substrate 101, a buried oxide (BOX) layer 102 and a silicon-on-insulator (SOI) layer 103. The semiconductor substrate 101 and the SOI layer 103 may comprise, but are not limited to, silicon (Si), germanium (Ge), or silicon-germanium (SiGe). According to an exemplary embodiment, the BOX layer 102 may have a thickness in the range of 3 to 175 nm, or possibly 5 to 145 nm. The SOI layer 103 may have a thickness in the range of 1 to 100 nm, or possibly 2 to 88 nm. However, the respective thicknesses of these layers is not limited thereto. Each of the layers may be formed by using a deposition technique such as, but not limited to, chemical vapor deposition (CPVD), low pressure CVD (LPCVD), atmospheric pressure CVD (APCVD), ultrahigh vacuum CVD (UHVCVD), aerosol assisted CVD (AACVD), direct liquid injection CVD (DLICVD), microwave plasma-assisted CVD (MPCVD), plasma-enhanced CVD (PECVD), atomic layer CVD (ALCVD), combustion CVD (CCVD), hot wire CVD (HWCVD), metalorganic CVD (MOCVD), hybrid physical CVD (HPCVD), rapid thermal CVD (RTCVD), molecular beam epitaxy (MBE), vapor phase epitaxy (VPE), plating, ion beam deposition, electron beam deposition, chemical solution deposition (CSD), thermal oxidation, cathodic arc deposition (arc-PVD), thermal nitridation or sputtering. In an exemplary embodiment, the semiconductor substrate 101 may include bulk crystalline Si. In another exemplary embodiment, the semiconductor substrate 101 may include non-planar multigate devices such as, for example, Trigates, FinFETs and nanowires.

A liner 104 may be deposited on the inner wall of the trench 105. The liner may be formed of a high temperature oxide (HTO), such as, for example, silicon oxide or nitride. The liner may also be formed of silicon nickel (SiN), which can be deposited by, for example, chemical vapor deposition (CVD), low pressure CVD (LPCVD) or atomic layer CVD (ALCVD).

The trench 105 may be filled with a shallow trench isolation (STI) dielectric, such as, for example, high aspect ratio process (HARP) oxide or high density plasma (HDP) oxide. The STI dielectric 105 separates a pFET region on one side of the device 100 from an nFET region on an opposing side of the device 100.

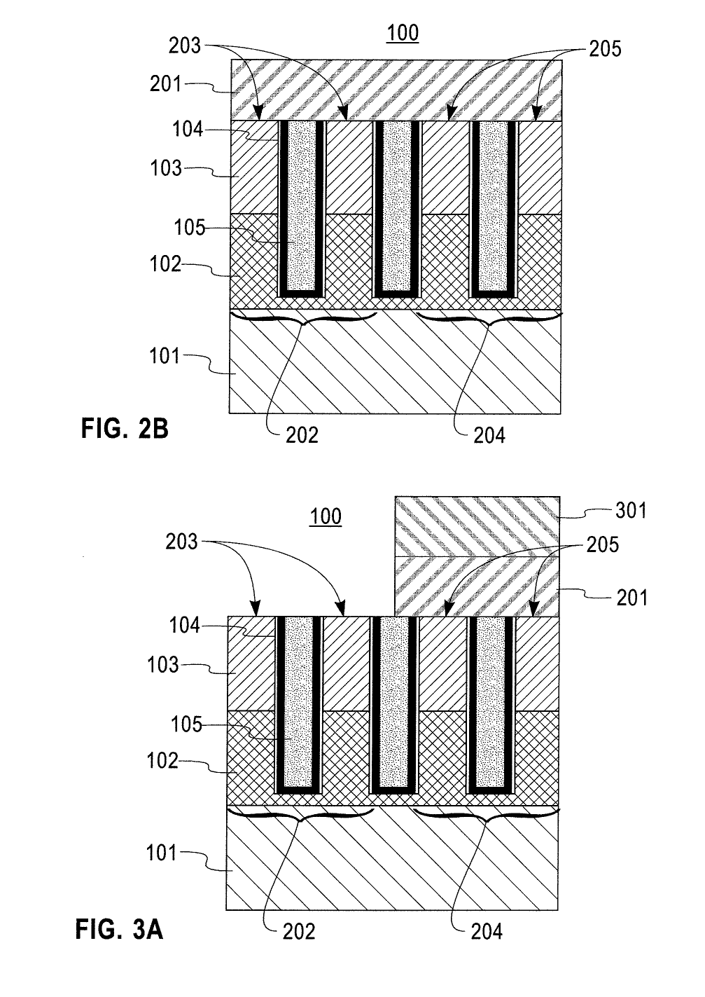

FIGS. 2A-2B depict a process of depositing a hard mask 201 on the top surface of the device 100, according to an exemplary embodiment of the present disclosure. As shown in FIGS. 2A-2B, a pFET region 202 of the device 100 comprises two p-channel regions 203 and an nFET region 204 of the device 100 comprises two n-channel regions 205. A pFET device may be formed in the pFET region 202 by epitaxially growing a semiconductor material in each of the p-channel regions 203. For example, a crystalline silicon-germanium (c-SiGe) film may be grown in each of the p-channel regions 203, respectively, as described in more detail below.

It is to be appreciated that although the exemplary embodiments described herein disclose epitaxially growing c-SiGe in the p-channel regions 203 of the device 100, the semiconductor material grown in the p-channel regions 203 is not limited to c-SiGe. Further, it is to be appreciated that although the exemplary embodiments described herein disclose depositing a hard mask 201 on the p-channel and n-channel regions 203 and 205, removing the hard mask 201 from the p-channel regions 203 and epitaxially growing a semiconductor film such as, for example, c-SiGe in the p-channel regions 203, an exemplary embodiment of the present disclosure may include depositing the hard mask 201 on both the p-channel and n-channel regions 203 and 205, removing the hard mask 201 from the n-channel regions 205 and epitaxially growing the semiconductor film such as, for example, c-SiGe in the n-channel regions 205.

After the c-SiGe film is grown in the p-channel regions 203, a gate region (not shown) is subsequently formed on the active channel of the c-SiGe film. According to an exemplary embodiment, an nFET device may be similarly formed in the nFET region 204. As shown in FIG. 2B, the hard mask 201 is deposited over a substantial portion of the top surface of the device 100, thus covering the pFET and nFET regions 202 and 204. The hard mask 201 is formed of a material that can withstand a number of cleaning steps such as, for example, hydrofluoric acid cleaning (HF cleaning), dry etching (e.g., chemical oxide reduction (COR), plasma cleaning), wet cleaning or a combination thereof. For example, according to an exemplary embodiment, the hard mask 201 may be formed of silicon or silicon nitride. In another exemplary embodiment, the hard mask 201 may include metal oxides and nitrides such as, for example, hafnium oxide (HfOx), aluminum oxide (AlOx), zirconium oxide (ZrOx), strontium oxide (SrOx), tungsten nitride (WN), titanium nitride (TiN), tantalum nitride (TaN), and combinations thereof. The hard mask 201 may be formed by using any of the deposition techniques described above, however formation of the hard mask 201 is not limited thereto.

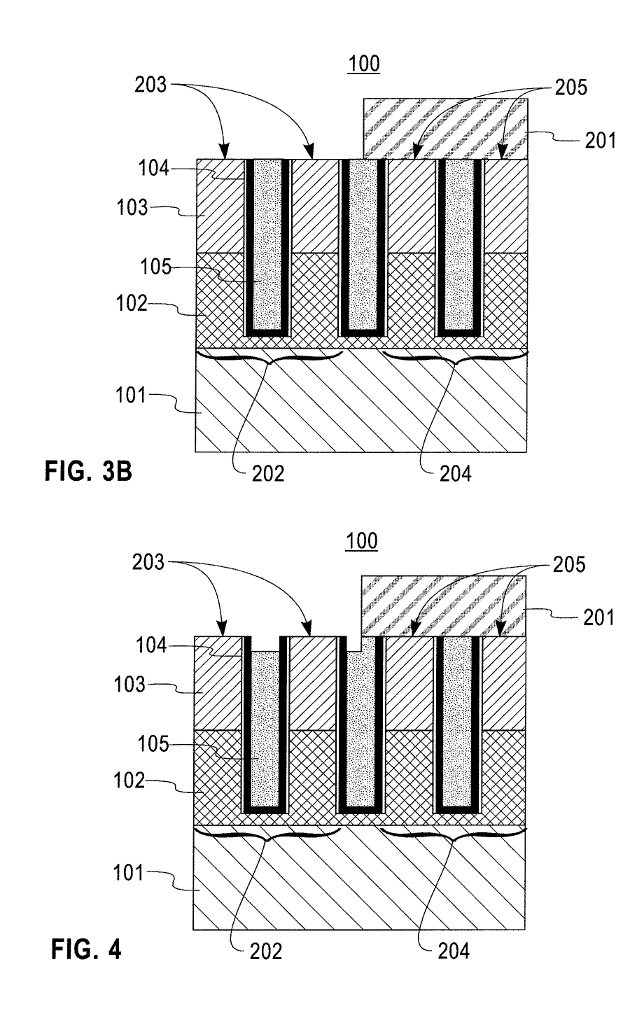

FIGS. 3A-3B depict a process of etching away a portion of the hard mask 201 and patterning the device 100 with a photoresist layer 301, according to an exemplary embodiment of the present disclosure. As shown in FIG. 3A, a patterned photoresist layer 301 may be deposited on the hard mask 201 above the nFET region 204. After deposition of the photoresist layer 301, the hard mask 201 deposited on the top surface of the pFET region 202 is etched away using a standard etching technique (e.g., reactive ion etching (RIE), dry etching, wet etching), as shown in FIG. 3A. As shown in FIG. 3B, once the hard mask 201 is removed from the top surface of the pFET region 202, the photoresist layer 301 is removed from the hard mask 201 formed on the top surface of the nFET region 204. The patterned photoresist layer 301 may be removed by, for example, an ashing process or a wet clean process utilizing, for example, a sulphuric-peroxide (piranha) mixture, or a combination thereof.

FIG. 4 depicts the semiconductor device 100 after a cleaning process has been performed, according to an exemplary embodiment of the present disclosure. The cleaning process is performed subsequent to the patterning process and prior to epitaxy. The cleaning process may be repeated a number of times, and may comprise cleaning the device 100 using, for example, hydrofluoric acid (e.g., HF cleaning), dry etching (e.g., chemical oxide reduction (COR), plasma clean), wet cleaning or a combination thereof. The cleaning process is performed to remove native oxide from the top surface of the device 100, as well as to repair damage caused to the top surface of the device 100 that may occur during the etching and patterning steps. As shown in FIG. 4, the cleaning process may result in the removal of a portion of the exposed STI dielectric 105. However, because the hard mask 201 is formed of a material that can withstand the cleaning process, as described above, the hard mask 201 is not removed during cleaning. As a result, when c-SiGe is subsequently grown during epitaxy, c-SiGe will not be grown on the nFET region 204. This process is described in more detail below.

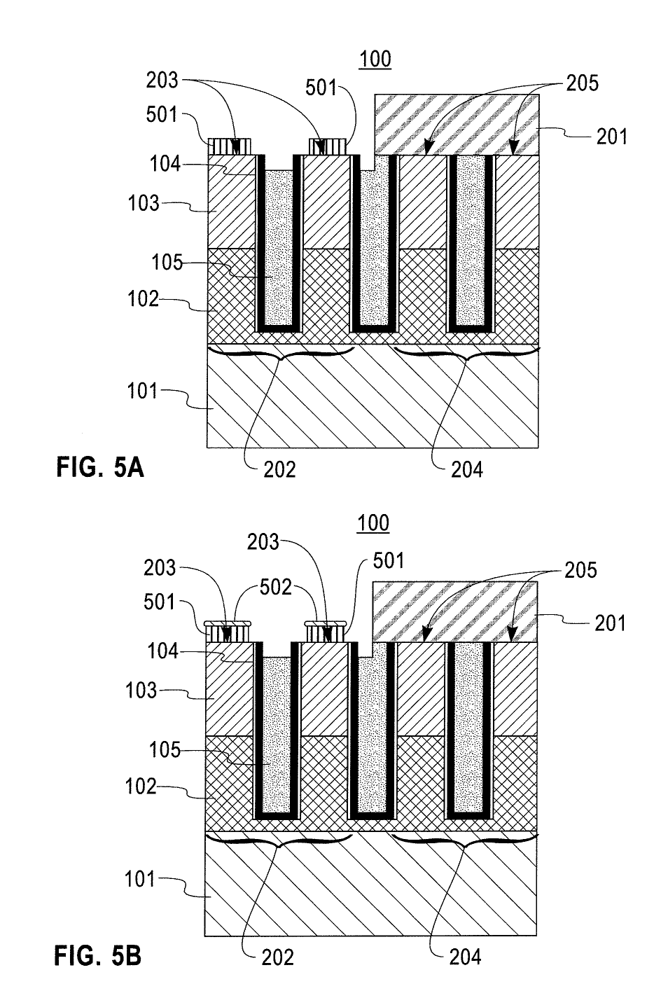

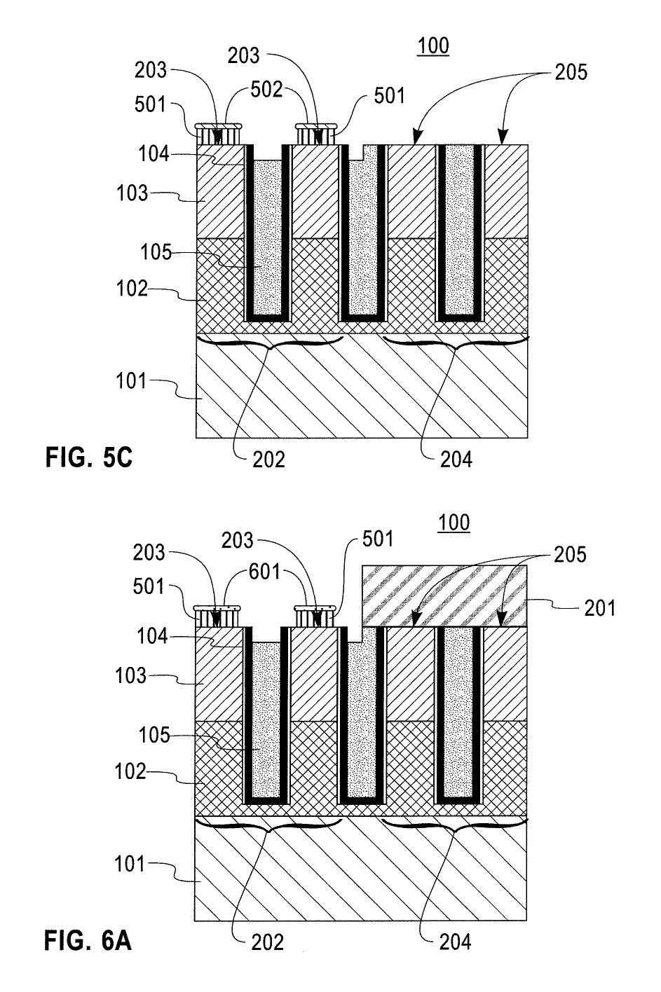

FIGS. 5A-5C depict a semiconductor material being epitaxially grown on the top surface of the p-channel regions 203 of the device 100, according to an exemplary embodiment of the present disclosure. FIG. 4 shows the device 100 prior to epitaxy. In FIG. 5A, a semiconductor material, such as, for example c-SiGe 501, is epitaxially grown on the top surface of the p-channel regions 203. The c-SiGe 501 grown in each of the p-channel regions 203 corresponds to the active channel, source and drain of a pFET device, and may be doped appropriately. As stated above, because the hard mask 201 on the top surface of the nFET region 204 is not etched away during the cleaning process, c-SiGe is not grown in the nFET region 204. In FIG. 5B, the top surface of the c-SiGe 501 is oxidized 502 in order to protect the c-SiGe 501 during removal of the hard mask 201 from the top surface of the nFET region 204, as shown in FIG. 5C. The hard mask 201 may be removed using a standard etching technique such as, for example, RIE, dry etching or wet etching.

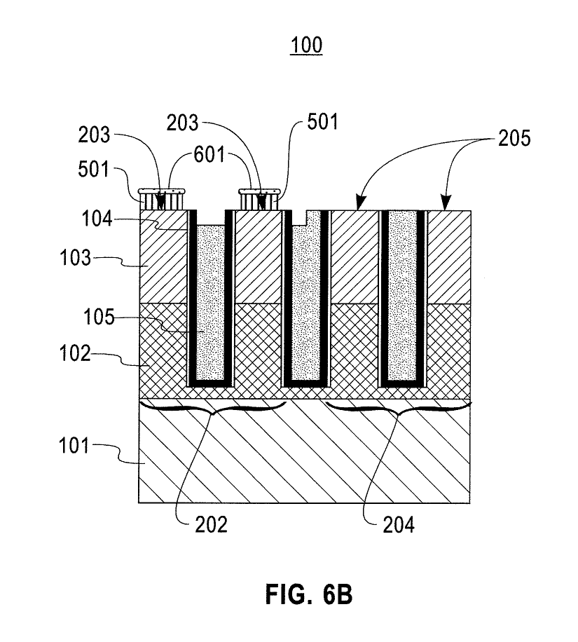

FIGS. 6A-6B depict a semiconductor material 501 and a silicon cap 601 being epitaxially grown on the top surface of the p-channel regions 203, according to another exemplary embodiment of the present disclosure. In FIG. 6A, a semiconductor material, such as, for example c-SiGe 501, and a silicon cap 601, are epitaxially grown on the top surface of the p-channel regions 203. The c-SiGe 501 grown in each of the p-channel regions 203 corresponds to the active channel, source and drain of a pFET device, and may be doped appropriately. As stated above, because the hard mask 201 on the top surface of the nFET region 204 is not etched away during the cleaning process, c-SiGe is not grown in the nFET region 204. The top surface of the silicon cap 601 is oxidized in order to protect the c-SiGe 501 during removal of the hard mask 201 from the top surface of the nFET region 204, as shown in FIG. 6B. The hard mask 201 may be removed using standard etching technique, such as, for example, RIE, dry etching or wet etching.

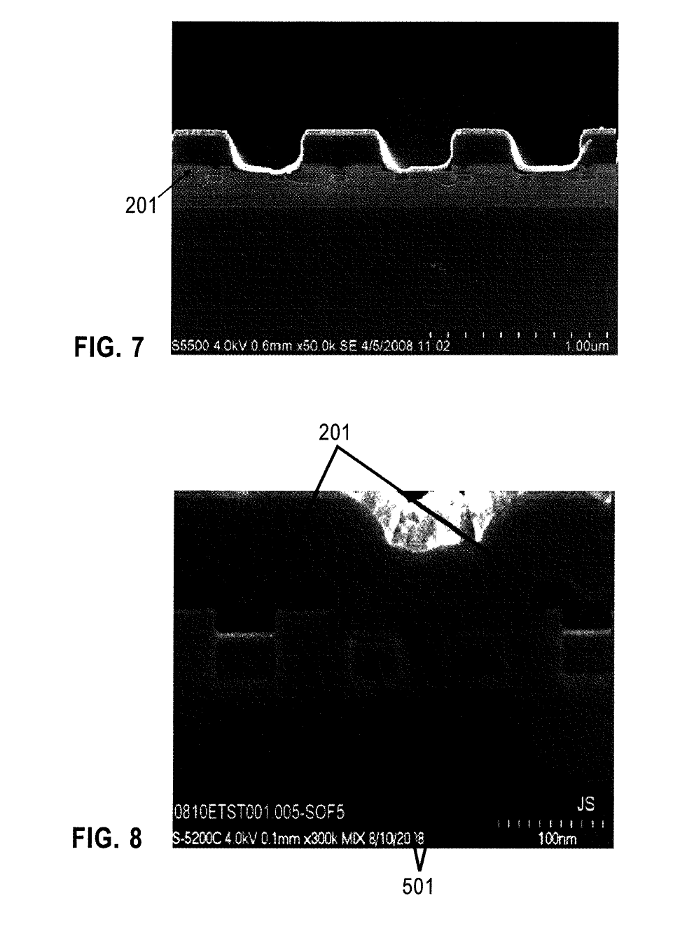

FIG. 7 is a cross-sectional view of the semiconductor device 100 illustrating the presence of the hard mask 201 above the top surface of the n-channel regions after the hard mask 201 has been patterned. As described above, the presence of the hard mask 201 prevents the epitaxial growth of c-SiGe in the n-channel regions of the device 100.

FIG. 8 is a cross-sectional view showing the epitaxial growth of c-SiGe according to an exemplary embodiment of the present disclosure. In FIG. 8, a hard mask 201 is formed of a material that can withstand a number of cleaning steps, as described above. Because the hard mask 201 remains on the top surface of the semiconductor device above the n-channel regions subsequent to the cleaning process, c-SiGe 501 is grown in the p-channel region of the device, but is not grown in the n-channel regions of the semiconductor device.

Although exemplary embodiments of the present disclosure have been described hereinabove, it is noted that modifications and variations can be made by persons skilled in the art in light of the above teachings. It is therefore to be understood that changes may be made in embodiments of the present disclosure which are within the scope and spirit of the disclosure as defined by the appended claims. Having thus described the invention with the details and particularity required by the patent laws, what is claimed and desired protected by Letters Patent is set forth in the appended claims.

What is claimed is:

1. A method of forming a semiconductor device, comprising:
forming a buried oxide (BOX)layer on a semiconductor substrate;
forming a silicon-on-insulator (SOI) layer on the BOX layer;
depositing a hard mask on the SOI layer, wherein the hard mask comprises at least one of silicon, a nitride, and a metal oxide;
removing the hard mask from a first region of the semiconductor device;
performing a cleaning process on the semiconductor device, wherein the hard mask is not removed from a second region of the semiconductor device by the cleaning process;
epitaxially growing a semiconductor material in the first region; and
removing the hard mask from the second region.

2. The method of claim 1, wherein the hard mask comprises at least one of silicon nitride (SiN), hafnium oxide (HfOx), aluminum oxide (AlOx), zirconium oxide (ZrOx), strontium oxide (SrOx), tungsten nitride (WN), titanium nitride (TiN) and tantalum nitride (TaN).

3. The method of claim 1, further comprising forming a p-type field effect transistor (pFET) device in the first region of the semiconductor device and an n-type field effect transistor (nFET) device in the second region of the semiconductor device.

4. The method of claim 1, further comprising forming an n-type field effect transistor (nFET) device in the first region of the semiconductor device and a p-type field effect transistor (pFET) device in the second region of the semiconductor device.

5. The method of claim 1, wherein epitaxially growing the semiconductor material in the first region comprises epitaxially growing crystalline silicon-germanium (c-SiGe).

6. The method of claim 1, wherein the BOX layer has a thickness from about 5 nm to about 145 nm.

7. The method of claim 1, wherein the SOI layer has a thickness from about 2 nm to about 88 nm.

8. The method of claim 1, wherein performing the cleaning process comprises performing at least one of hydrofluoric acid cleaning, dry etching and wet cleaning.

9. The method of claim 1, wherein removing the hard mask from the first region of the semiconductor device comprises:
depositing a photoresist pattern on the second region of the semiconductor device; and
removing the hard mask from the first region of the semiconductor device using an etching technique.

10. The method of claim 9, wherein the hard mask is removed from the first region of the semiconductor device using one of reactive ion etching, dry etching and wet etching.

11. The method of claim 1, wherein the semiconductor substrate comprises one of bulk crystalline silicon, trigates, FinFETS and nanowires.

12. The method of claim 1, further comprising epitaxially growing a silicon cap on the semiconductor material in the first region of the semiconductor device.

13. The method of claim 12, further comprising oxidizing the silicon cap.

14. The method of claim 1, further comprising oxidizing the semiconductor material in the first region of the semiconductor device.

15. The method of claim 1, further comprising depositing a liner on an inner wall of a trench of the semiconductor device.

16. A semiconductor device, comprising:
a buried oxide (BOX) layer formed on a semiconductor substrate;
a silicon-on-insulator (SOI) layer formed on the BOX layer;
a semiconductor material epitaxially grown in a first region of the semiconductor device; and
a hard mask comprising at least one of silicon, a nitride and a metal oxide formed on a second region of a semiconductor device.

17. The semiconductor device of claim 16, wherein the hard mask comprises at least one of silicon nitride (SiN), hafnium oxide (HfOx), aluminum oxide (AlOx), zirconium oxide (ZrOx), strontium oxide (SrOx), tungsten nitride (WN), titanium nitride (TiN) and tantalum nitride (TaN).

18. The semiconductor device of claim 16, wherein the semiconductor material epitaxially grown in the first region of the semiconductor device comprises crystalline silicon-germanium (c-SiGe).

19. The semiconductor device of claim 16, wherein the first region of the semiconductor device comprises a p-type field effect transistor (pFET) device and the second region of the semiconductor device comprises an n-type field effect transistor (nFET) device.

20. The semiconductor device of claim 16, wherein the first region of the semiconductor device comprises an n-type field effect transistor (nFET) device and the second region of the semiconductor device comprises a p-type field effect transistor (pFET) device.
